(19) United States
(12) Patent Application Publication
(10) Pub. No.: US 2026/0122765 A1
(43) Pub. Date: Apr. 30, 2026

(54) DIFFERENTIAL SIGNAL TRANSMISSION CIRCUIT, CIRCUIT BOARD, ELECTRONIC DEVICE, AND CIRCUIT MANUFACTURING METHOD

(71) Applicant: Suzhou MetaBrain Intelligent Technology Co., Ltd., Suzhou, Jiangsu (CN)

(72) Inventor: Lei LIANG, Suzhou, Hiangsu (CN)

(21) Appl. No.: 19/145,248

(22) PCT Filed: Aug. 31, 2023
(86) PCT No.: PCT/CN2023/116253

§ 371 Date: Jul. 2, 2025

(30) Foreign Application Priority Data
Jan. 9, 2023 (CN) 202310027241.4

(51) Int. Cl. H05K 1/02; H05K 3/00; H05K 3/40

(52) U.S. Cl. CPC H05K 1/0213; H05K 3/0005; H05K 3/0047; H05K 3/4038

(57) ABSTRACT

The present application relates to the technical field of printed circuit boards, and provides a differential signal transmission circuit, a circuit board, an electronic device, and a circuit manufacturing method. For the differential signal transmission circuit, the following is formed on a surface layer of a circuit board: a peripherally closed pattern, a first pattern, a second pattern, and a third pattern; the first pattern, the second pattern, and the third pattern are all surrounded by the peripherally closed pattern; the first pattern, the second pattern, and the third pattern are isolated by a dielectric; the first pattern and the second pattern are axisymmetric; the first pattern and the second pattern are respectively connected to an inner signal layer by means of an inner wall plating layer of the circuit board; and the third pattern is used to form a return current path.

### CROSS-REFERENCE TO RELATED APPLICATION

This application claims priority to Chinese Patent Application No. 202310027241.4, entitled “Differential Signal Transmission Circuit, Circuit Board, Electronic Device, and Circuit Manufacturing Method” filed to the China National Intellectual Property Administration on Jan. 9, 2023, which is incorporated herein by reference in its entirety.

### FIELD

The present application relates to the technical field of printed circuit boards, in particular to a differential signal transmission circuit, a circuit board, an electronic device, and a circuit manufacturing method.

### BACKGROUND

With the development trend of electronic devices towards multi-functionality and miniaturization, the density of a printed circuit board (PCB), which serves as a carrier for a hardware circuit, is gradually increasing. In general cases, electronic components are arranged on an outer layer of the printed circuit board; and high-speed signal traces are arranged on an inner layer of the printed circuit board, and layer switching is achieved through via holes, so as to ensure the signal integrity. On a planar structure, a pair of differential signal holes are generally accompanied by a return ground via hole, respectively. FIG. 1 shows a planar connection mode of via holes and high-speed signal lines, wherein a basic structure of each via hole includes a drilled hole, a pad and an anti-pad. The anti-pad is filled with an insulating medium to isolate the metal pad from a grounding metal layer, thereby avoiding short circuiting between the via holes and a grounding layer. A pair of high-speed signal lines often requires at least two pairs of differential via holes for layer switching, which results in a very large number of return ground via holes on a PCB, takes up a lot of space on the printed circuit board and compresses a wiring space. Simply removing the return ground via holes will seriously affect the signal quality because a signal has no return path. The traditional solution to this problem is to increase wiring layers. However, the thickness and cost of the board are increased accordingly, affecting the competitiveness of the product.

### SUMMARY

According to a first aspect of the present application, a differential signal transmission circuit is provided. For the differential signal transmission circuit, the following is formed on a surface layer of a circuit board: a peripherally closed pattern, a first pattern, a second pattern, and a third pattern, wherein

the first pattern, the second pattern, and the third pattern are all surrounded by the peripherally closed pattern;

the first pattern, the second pattern, and the third pattern are isolated by a dielectric;

the first pattern and the second pattern are axisymmetric;

the first pattern and the second pattern are respectively connected to an inner signal layer by means of an inner wall plating layer of the circuit board; and

the third pattern is used to form a return current path.

In some embodiments, the third pattern is connected to the peripherally closed pattern through a preset pattern arranged on the surface layer of the circuit board.

In some embodiments, the preset pattern is arranged on an axis of symmetry of the first pattern and the second pattern.

In some embodiments, the peripherally closed pattern, the first pattern, the second pattern, the third pattern, and the preset pattern are made of a metal material.

In some embodiments, a differential impedance of the first pattern and the second pattern is within a preset impedance range.

In some embodiments, the preset impedance range is 85-100Ω.

According to a second aspect of the present application, a circuit board is provided. The circuit board includes the differential signal transmission circuit according to the first aspect.

In some embodiments, the circuit board includes a surface layer and a signal layer, wherein

the surface layer is provided with a peripherally closed pattern, a first pattern, a second pattern, and a third pattern; and

the signal layer is electrically connected to the first pattern and the second pattern respectively by means of an inner wall plating layer of the circuit board.

In some embodiments, the circuit board is a printed circuit board.

According to a third aspect of the present application, an electronic device is provided. The electronic device includes the circuit board according to the second aspect.

According to a fourth aspect of the present application, a method for manufacturing a differential signal transmission circuit is provided. The method is used to manufacture the differential signal transmission circuit according to the first aspect and includes:

drilling truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of an rectangular frame; the preset position is located on a pattern of the pad; the truncation hole has a preset radius; the first pattern and the second pattern are axisymmetric; and the first pattern, the second pattern, and the third pattern are separated from each other;

simulating the first pattern and the second pattern to generate an impedance simulation result of the first pattern and the second pattern; and

adjusting an impedance of the first pattern and an impedance of the second pattern according to the impedance simulation result.

In some embodiments, acquiring the preset positions includes:

invoking a simulation tool to perform simulated biasing on a center position of each truncation hole; and

in response to the impedance simulation result of the first pattern and the second pattern being within a preset impedance range, drilling the truncation hole using the center position of the truncation hole as the preset position and the radius of the truncation hole as a preset radius.

In some embodiments, the adjusting the impedance of the first pattern and the impedance of the second pattern according to the impedance simulation result includes:

adjusting the center position and the preset radius of the truncation hole.

In some embodiments, the adjusting the impedance of the first pattern and the impedance of the second pattern according to the impedance simulation result further includes:

in response to the impedance of the first pattern and the impedance of the second pattern being greater than a maximum value of the preset impedance range, filling the truncation hole and the center hole with a dielectric material so that the impedance is reduced; and

in response to the impedance of the first pattern and the impedance of the second pattern being less than a minimum value of the preset impedance range, adjusting the preset positions, and drilling truncation holes at the preset positions on the surface metal pattern again to form the first pattern, the second pattern and the third pattern.

In some embodiments, the dielectric material is resin.

In some embodiments, the resin has a relative dielectric constant of 3.5.

In some embodiments, the method further includes: identifying the surface metal pattern.

In some embodiments, in response to the identification result indicating that the peripherally closed pattern is annular, the method further includes:

backfilling a dielectric material between the first pattern and the second pattern;

drilling a central ground hole in the center of the annular peripherally closed pattern, wherein a radius of the central ground hole is a first preset radius;

plating a metal layer on an inner wall of the central ground hole; and

manufacturing a metal wire along the axis of symmetry of the first pattern and the second pattern, so that the central ground hole is electrically connected to the peripherally closed pattern.

In some embodiments, the first preset radius is less than a shortest distance from the center to the first pattern.

In some embodiments, in response to the identification result indicating that the peripherally closed pattern is in the shape of a rectangular frame, prior to drilling the truncation holes at the preset positions of the surface metal pattern, the method further includes:

manufacturing a metal connection pattern between a long side of the pad and the peripherally closed pattern, so that the pad is electrically connected to the peripherally closed pattern.

According to a fifth aspect of the present application, an apparatus for manufacturing a differential signal transmission circuit is provided. The apparatus includes:

a drilling module, configured to drill truncation holes at preset positions on a surface metal pattern to form a first pattern, a second pattern, and a third pattern, wherein the surface metal pattern comprises from outside to inside: a peripherally closed pattern, an anti-pad, a pad, and a center hole; the pad is an annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

a simulation module, configured to simulate the first pattern and the second pattern to generate an impedance simulation result of the first pattern and the second pattern; and

an impedance adjusting module, configured to adjust an impedance of the first pattern and an impedance of the second pattern according to the impedance simulation result.

### BRIEF DESCRIPTION OF THE DRAWINGS

To describe the technical solutions of the embodiments of the present application more clearly, the following briefly introduces the accompanying drawings required for describing the embodiments. Apparently, the accompanying drawings in the following description show only some embodiments of the present application, and a person of ordinary skill in the art may still derive other drawings from these accompanying drawings without creative efforts.

FIG. 1 is a schematic diagram of a connection mode of differential signal holes and signal traces;

FIG. 2 is a schematic structural diagram of a surface layer of a circuit board of a differential signal transmission circuit provided by one or more embodiments of the present application;

FIG. 3 is a schematic diagram of a method for manufacturing a differential signal transmission circuit provided by one or more embodiments of the present application;

FIG. 4 is a schematic diagram of an annular surface metal layer provided by one or more embodiments of the present application;

FIG. 5 is a schematic diagram of a rectangular surface metal layer provided by one or more embodiments of the present application;

FIG. 6 is a schematic diagram of an angle a provided by one or more embodiments of the present application;

FIG. 7 is a schematic diagram of a corresponding relationship between a differential impedance and an angle a provided by one or more embodiments of the present application;

FIG. 8 is a schematic structural diagram of a surface layer of a circuit board of a differential signal transmission circuit corresponding to a rectangular surface metal layer provided by one or more embodiments of the present application; and

FIG. 9 is a schematic diagram of an apparatus for manufacturing a differential signal transmission circuit provided by one or more embodiments of the present application.

### DETAILED DESCRIPTION

In order to make the objectives, technical solutions and advantages of the present application more clearly, the technical solutions in the embodiments of the present application will be described clearly and completely in conjunction with the accompanying drawings in the embodiments of the present application. Apparently, the described embodiments are merely some embodiments, rather than all embodiments, of the present application. Based on the examples of the present application, all other examples derived by a person of ordinary skill in the art without creative efforts shall fall within the protection scope of the present application.

The technical and scientific terms as used in the present disclosure should have the meanings as commonly understood by a person of ordinary skill in the art of the present disclosure, unless otherwise defined. The words “first”, “second” and similar terms used in the present application do not denote any order, quantity, or importance, and are merely used to distinguish different components. Similarly, words such as “a”, “one” or “the” do not denote a quantitative limit, but rather the existence of at least one. The numbers in the drawings of the specification only indicate the distinction of various functional components or modules, and do not indicate a logical relationship between the components or modules. The word “comprise”, “containing” or similar terms mean that elements or objects appearing before the term cover the listed elements or objects and its equivalents appearing after the term while other elements or objects are not excluded. The word “connected to” or “connected with” and similar terms are not limited to physical or mechanical connections, and may include electrical connection and the connection may be direct or indirect. “Upper”, “lower”, “left”, “right” and the like are only used to indicate the relative positional relationship, and when the absolute position of a described object changes, the relative positional relationship may also change accordingly.

The embodiments of the present application are described in detail below with reference to the accompanying drawings. It should be noted that in the accompanying drawings, the same reference signs are assigned to constituent parts that have basically the same or similar structures and functions, and the repetitive descriptions regarding these constituent parts will be omitted.

In view of the problem in the prior art that differential signal via holes arranged on a circuit board occupy a large area of the circuit board, or the increase in the number of layers of the circuit board increases the thickness of the circuit board and the cost, embodiments of the present application provide a differential signal transmission circuit, a circuit board, an electronic device and a circuit manufacturing method, which might significantly reduce an area of a printed circuit board occupied by high-speed signal holes relative to the arrangement of the current high-speed signal holes. By reducing the area of the printed circuit board occupied by the high-speed signal holes, a lot of space might be saved for the arrangement of high-speed signal traces, so as to avoid the additional number of layers of the printed circuit board for wiring due to insufficient signal trace space. By limiting the number of layers of the circuit board, the cost of a high-speed signal board is effectively reduced, and the product competitiveness is improved.

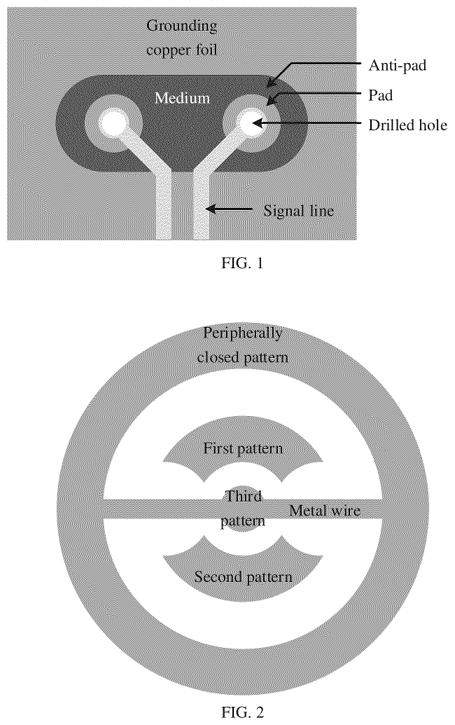

In one embodiment, as shown in FIG. 2, a differential signal transmission circuit is shown. For the differential signal transmission circuit, the following is formed on a surface layer of a circuit board: a peripherally closed pattern, a first pattern, a second pattern, and a third pattern, wherein

the first pattern, the second pattern, and the third pattern are all surrounded by the peripherally closed pattern;

the first pattern, the second pattern, and the third pattern are isolated by a dielectric;

the first pattern and the second pattern are axisymmetric;

the first pattern and the second pattern are respectively connected to an inner signal layer by means of an inner wall plating layer of the circuit board; and

the third pattern is used to form a return current path.

In some embodiments, the third pattern is connected to the peripherally closed pattern through a preset pattern arranged on the surface layer of the circuit board.

In some embodiments, the preset pattern is arranged on an axis of symmetry of the first pattern and the second pattern. The preset pattern may be a rectangle with a certain length and width. A specific value of the length or width is determined by specific shapes of the peripherally closed pattern, the first pattern, the second pattern, and the third pattern.

The peripherally closed pattern, the first pattern, the second pattern, the third pattern, and the preset pattern are all made of a metal material.

In some embodiments, the metal material is copper.

A differential impedance of the first pattern and the second pattern is within a preset impedance range.

In some embodiments, the preset impedance range is 85-100Ω.

In another embodiment, a circuit board includes the differential signal transmission circuit according to the first aspect. The circuit board includes a surface layer and a signal layer, wherein

the surface layer is provided with a peripherally closed pattern, a first pattern, a second pattern, and a third pattern; and

the signal layer is electrically connected to the first pattern and the second pattern respectively by means of an inner wall plating layer of the circuit board.

In some embodiments, the circuit board is a printed circuit board.

In another embodiment, an electronic device includes the circuit board according to the second aspect.

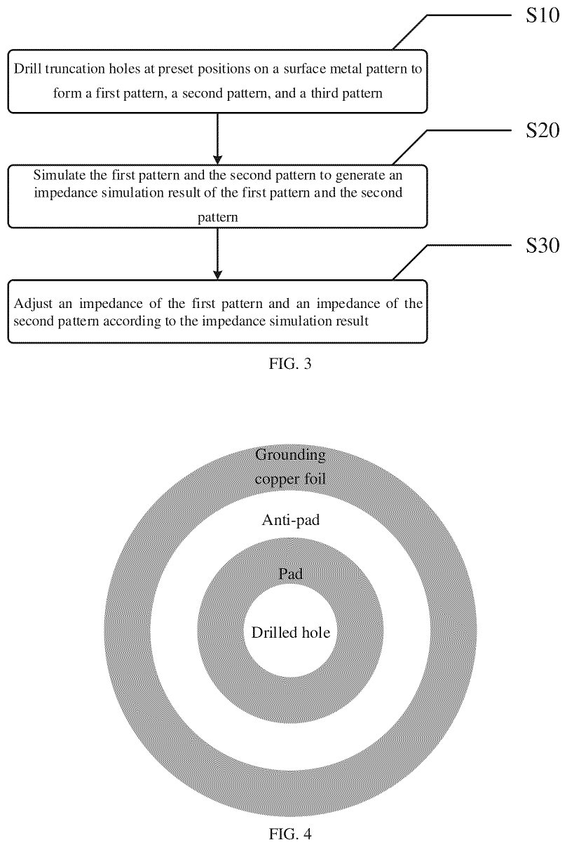

In another embodiment, a method for manufacturing a differential signal transmission circuit is shown in FIG. 3. The method is used to manufacture the differential signal transmission circuit according to the first aspect and includes:

S10: drilling truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

S20: simulating the first pattern and the second pattern to generate an impedance simulation result of the first pattern and the second pattern; and

S30: adjusting an impedance of the first pattern and an impedance of the second pattern according to the impedance simulation result.

FIG. 4 shows a surface metal layer, on which an annular grounding copper foil, an annular anti-pad, an annular pad, and a circular drilled hole are arranged from outside to inside. The annular grounding copper foil and the annular pad are made of a copper material.

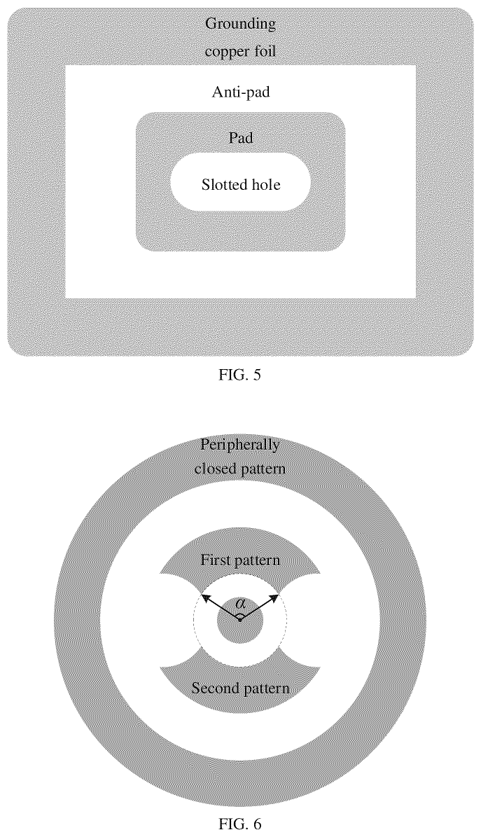

FIG. 5 shows another surface metal layer, on which a rectangular-frame-shaped grounding copper foil, a rectangular-frame-shaped anti-pad, a rectangular-frame-shaped pad, and a rounded rectangle slotted hole are sequentially arranged from outside to inside. The rectangular-frame-shaped grounding copper foil and the rectangular-frame-shaped pad are made of copper.

In another embodiment, acquiring the preset positions includes:

S11: invoking a simulation tool to perform simulated biasing on a center position of each truncation hole; and

S12: in response to the impedance simulation result of the first pattern and the second pattern being within a preset impedance range, drilling the truncation hole using the center position of the truncation hole as the preset position and the radius of the truncation hole as a preset radius.

As an alternatively simulation method, as shown in FIG. 6, the impedance simulation result is adjusted by adjusting a central angle α formed from the center of the third pattern to two nearest vertices of the first pattern or the second pattern. Therefore, the differential impedance of the first pattern, the second pattern and the corresponding plating metal layer for differential signal transmission is in the range of 85-100Ω.

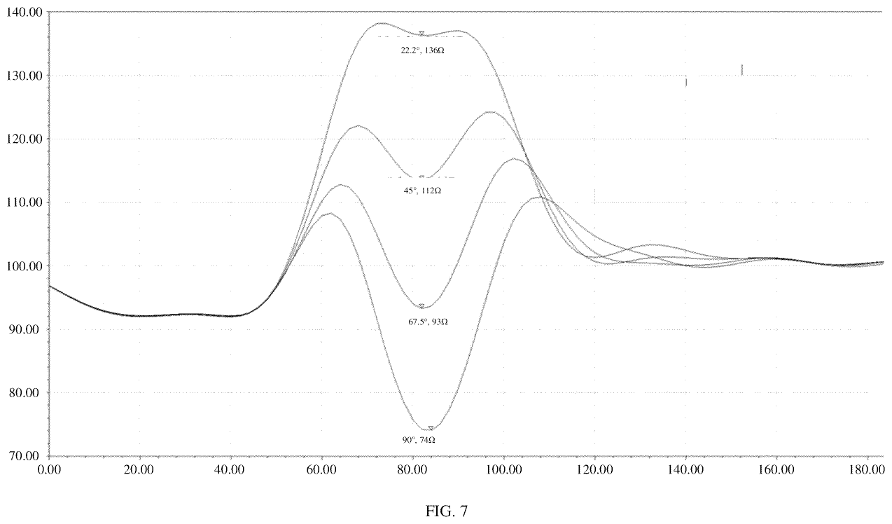

FIG. 7 shows a corresponding relationship between the differential impedance and the angle α.

The adjusting the impedance of the first pattern and the impedance of the second pattern according to the impedance simulation result includes:

S31: in response to the impedance of the first pattern and the impedance of the second pattern being greater than a maximum value of the preset impedance range, filling the truncation holes and the center hole with a dielectric material so that the impedance is reduced; and

S32: in response to the impedance of the first pattern and the impedance of the second pattern being less than a minimum value of the preset impedance range, adjusting the preset positions, and drilling truncation holes at the preset positions on the surface metal pattern again to form the first pattern, the second pattern and the third pattern.

In some embodiments, the dielectric material is resin.

In some embodiments, the resin has a relative dielectric constant of 3.5.

In another embodiment, the method further includes: S00: identifying a surface metal pattern.

In response to the identification result indicating that the peripherally closed pattern is annular, the method further includes:

S41′: backfilling a dielectric material between the first pattern and the second pattern;

S42′: drilling a central ground hole in the center of the annular peripherally closed pattern, wherein a radius of the central ground hole is a first preset radius r1;

S43′: plating a metal layer on an inner wall of the central ground hole; and

S44′: manufacturing a metal wire along the axis of symmetry of the first pattern and the second pattern, so that the central ground hole is electrically connected to the peripherally closed pattern.

In this case, the metal wire is the preset pattern.

The first preset radius r1 is less than a shortest distance from the center to the first pattern.

FIG. 2 shows a structure of a surface layer of a circuit board of a differential signal transmission circuit corresponding to FIG. 4 manufactured by using the method for manufacturing the differential signal transmission circuit.

In response to an indicating result indicating that the peripherally closed pattern is in the shape of a rectangular frame, prior to drilling the truncation holes at the preset positions on the surface metal pattern, the method further includes:

S01″: manufacturing a metal connection pattern between a long side of the pad and the peripherally closed pattern, so that the pad is electrically connected to the peripherally closed pattern.

In this case, the metal connection pattern is the preset pattern.

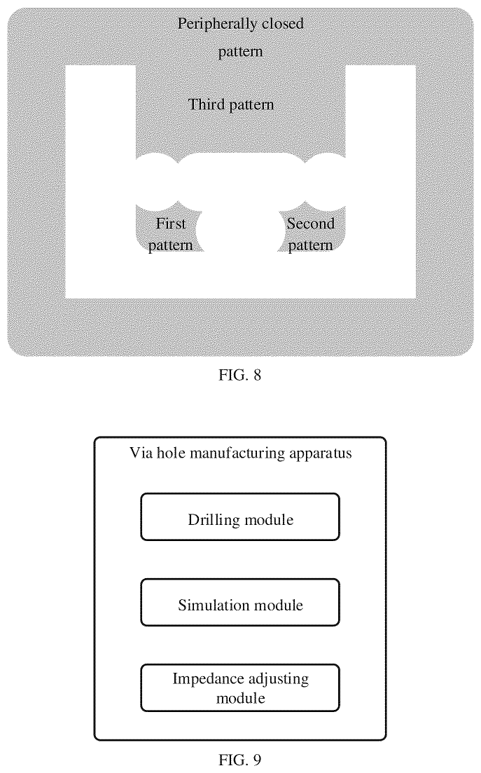

FIG. 8 shows a structure of a surface layer of a circuit board of a differential signal transmission circuit corresponding to FIG. 5 manufactured by using the method for manufacturing the differential signal transmission circuit.

In another embodiment, as shown in FIG. 9, an apparatus for manufacturing a differential signal transmission circuit includes:

a drilling module, configured to drill truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

a simulation module, configured to simulate the first pattern and the second pattern to generate an impedance simulation result of the first pattern and the second pattern; and

an impedance adjusting module, configured to adjust an impedance of the first pattern and an impedance of the second pattern according to the impedance simulation result.

The specific restrictions on the apparatus for manufacturing the differential signal transmission circuit might be found in the above restrictions on the method for manufacturing the differential signal transmission circuit, and will not be repeated here. The respective modules in the apparatus for manufacturing the differential signal transmission circuit may be implemented entirely or partially through software, hardware, or a combination thereof.

By implementing the differential signal transmission circuit, the circuit board, the electronic device and the circuit manufacturing method, an area of a printed circuit board occupied by high-speed signal holes might be significantly increased relative to the arrangement of the current high-speed signal holes. By reducing the area of the printed circuit board occupied by the high-speed signal holes, a lot of space might be saved for the arrangement of high-speed signal traces, so as to avoid the additional number of layers of the printed circuit board for wiring due to insufficient signal trace space. By limiting the number of layers of the circuit board, the cost of a high-speed signal board is effectively reduced, and the product competitiveness is improved.

An optional embodiment of the present application may be formed by using any combination of all the foregoing optional technical solutions, and details are not described herein.

Another aspect of the present application provides a differential signal transmission circuit. For the differential signal transmission circuit, the following is formed on a surface layer of a circuit board: a peripherally closed pattern, a first pattern, a second pattern, and a third pattern, wherein

the first pattern, the second pattern, and the third pattern are all surrounded by the peripherally closed pattern;

the first pattern, the second pattern, and the third pattern are isolated by a dielectric;

the first pattern and the second pattern are axisymmetric;

the first pattern and the second pattern are respectively connected to an inner signal layer by means of an inner wall plating layer of the circuit board; and

the third pattern is used to form a return current path.

Yet another aspect of the present application provides a differential signal transmission circuit. For the differential signal transmission circuit, the following is formed on a surface layer of a circuit board: a peripherally closed pattern, a first pattern, a second pattern, and a third pattern, wherein

the first pattern, the second pattern, and the third pattern are all surrounded by the peripherally closed pattern;

the first pattern, the second pattern, and the third pattern are isolated by a dielectric;

the first pattern and the second pattern are axisymmetric;

the first pattern and the second pattern are respectively connected to an inner signal layer by means of an inner wall plating layer of the circuit board; and

the third pattern is used to form a return current path.

In some embodiments, the third pattern is connected to the peripherally closed pattern through a preset pattern arranged on the surface layer of the circuit board.

The preset pattern is arranged on an axis of symmetry of the first pattern and the second pattern. The preset pattern may be a rectangle with a certain length and width. A specific value of the length or width is determined by specific shapes of the peripherally closed pattern, the first pattern, the second pattern, and the third pattern.

The peripherally closed pattern, the first pattern, the second pattern, the third pattern, and the preset pattern are all made of a metal material. The metal material is copper.

A differential impedance of the first pattern and the second pattern is within a preset impedance range. The preset impedance range is 85-100Ω.

In some embodiments, a circuit board includes the differential signal transmission circuit described above. The circuit board is a printed circuit board, and electrical signals transmitted by the circuit board include at least differential signals. The circuit board includes a surface layer and a signal layer, wherein

the surface layer is provided with a peripherally closed pattern, a first pattern, a second pattern, and a third pattern; and

the signal layer is electrically connected to the first pattern and the second pattern respectively by means of an inner wall plating layer of the circuit board.

Still another aspect of the present application provides an electronic device, which includes the circuit board described in Embodiment 3.

Still another aspect of the present application provides a method for manufacturing a differential signal transmission circuit. As shown in FIG. 3, the method is used to manufacture a differential signal transmission circuit and includes:

S10: drilling truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

S20: simulating the first pattern and the second pattern to generate an impedance simulation result of the first pattern and the second pattern; and

S30: adjusting an impedance of the first pattern and an impedance of the second pattern according to the impedance simulation result.

Still another aspect of the present application provides a method for manufacturing a differential signal transmission circuit. As shown in FIG. 4, the method is used to manufacture a differential signal transmission circuit whose peripherally closed pattern is annular and includes:

S00: identifying a surface metal pattern, wherein the identification result indicates that the peripherally closed pattern is annular;

S10: drilling truncation holes at preset positions on the surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

S11: invoking a simulation tool to perform simulated biasing on a center position of each truncation hole;

S12: in response to the impedance simulation result of the first pattern and the second pattern being within a preset impedance range of 85-100Ω, using the center position of the truncation hole as the preset position;

S20: simulating the first pattern and the second pattern to generate an impedance simulation result of the first pattern and the second pattern;

S30: adjusting an impedance of the first pattern and an impedance of the second pattern according to the impedance simulation result;

S31: in response to the impedance of the first pattern and the impedance of the second pattern being greater than a maximum value of the preset impedance range, filling the truncation holes and the center hole with a dielectric material so that the impedance is reduced;

S32: in response to the impedance of the first pattern and the impedance of the second pattern being less than a minimum value of the preset impedance range, adjusting the preset positions, and drilling truncation holes at the preset positions on the surface metal pattern again to form the first pattern, the second pattern, and the third pattern;

S41′: backfilling a dielectric material between the first pattern and the second pattern;

S42′: drilling a central ground hole in the center of the annular peripherally closed pattern, wherein a radius of the central ground hole is a first preset radius r1;

S43′: plating a metal layer on an inner wall of the central ground hole; and

S44′: manufacturing a metal wire along the axis of symmetry of the first pattern and the second pattern, so that the central ground hole is electrically connected to the peripherally closed pattern.

The structure of the surface layer of the circuit board of the differential signal transmission circuit shown in FIG. 2 is obtained.

Still another aspect of the present application provides a method for manufacturing a differential signal transmission circuit. As shown in FIG. 5, the method is used to manufacture a differential signal transmission circuit whose peripherally closed pattern is in the shape of a rectangular frame and includes:

S00: identifying a surface metal pattern, wherein the identification result indicates that the peripherally closed pattern is in the shape of a rectangular frame;

S01″: manufacturing a metal connection pattern between a long side of the pad and the peripherally closed pattern, so that the pad is electrically connected to the peripherally closed pattern;

S10: drilling truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

S11: invoking a simulation tool to perform simulated biasing on a center position of each truncation hole; and S12: in response to the impedance simulation result of the first pattern and the second pattern being within a preset impedance range of 85-100Ω, using the center position of the truncation hole as the preset position;

S20: simulating the first pattern and the second pattern to generate an impedance simulation result of the first pattern and the second pattern;

S30: adjusting an impedance of the first pattern and an impedance of the second pattern according to the impedance simulation result;

S31: in response to the impedance of the first pattern and the impedance of the second pattern being greater than a maximum value of the preset impedance range, filling the truncation holes and the center hole with a dielectric material so that the impedance is reduced;

S32: in response to the impedance of the first pattern and the impedance of the second pattern being less than a minimum value of the preset impedance range, adjusting the preset positions, and drilling truncation holes at the preset positions on the surface metal pattern again to form the first pattern, the second pattern, and the third pattern;

S41′: backfilling a dielectric material between the first pattern and the second pattern;

S42′: drilling a central ground hole in the center of the annular peripherally closed pattern, wherein a radius of the central ground hole is a first preset radius r1;

S43′: plating a metal layer on an inner wall of the central ground hole; and

S44′: manufacturing a metal wire along the axis of symmetry of the first pattern and the second pattern, so that the central ground hole is electrically connected to the peripherally closed pattern.

The structure of the surface layer of the circuit board of the differential signal transmission circuit shown in FIG. 8 is obtained.

Another aspect of the present application provides an apparatus for manufacturing a differential signal transmission circuit. As shown in FIG. 9, the apparatus includes:

a drilling module, configured to drill truncation holes at preset positions on a surface metal pattern to form a first pattern, a second pattern, and a third pattern, wherein the surface metal pattern includes from outside to inside: a peripherally closed pattern, an anti-pad, a pad, and a center hole; the pad is annular or in the shape of a rectangular frame; the preset position is located on a pattern of the pad; the truncation hole has a preset radius; the first pattern and the second pattern are axisymmetric; and the first pattern, the second pattern, and the third pattern are separated from each other;

a simulation module, configured to simulate the first pattern and the second pattern to generate an impedance simulation result of the first pattern and the second pattern; and

an impedance adjusting module, configured to adjust an impedance of the first pattern and an impedance of the second pattern according to the impedance simulation result.

In particular, according to the embodiments of the present application, the process described above with reference to the flowchart may be implemented as a computer software program. For example, an embodiment of the present application includes a computer program product. The computer program product includes computer-readable instructions loaded on a computer-readable medium, the computer program including program codes configured to perform the method shown in the flowchart. In such an embodiment, the computer-readable instructions may be downloaded and installed from the network via a communication apparatus, or installed from a memory, or installed from ROM. In response to the computer-readable instructions being executed by an external processor, the above functions as defined in the method of the embodiments of the present application are performed.

It should be noted that the computer-readable medium described in the embodiment of the present application may be a computer-readable signal medium or a computer-readable storage medium, or any combination of the two. The computer-readable storage medium may be, for example, but not limited to electrical, magnetic, optical, electromagnetic, infrared, or semiconductor systems, apparatuses or devices, or any combination thereof. More specific examples of the computer-readable storage medium include, but are not limited to: an electric connector having one or more leads, a portable computer disk, a hard disk, a random access memory (RAM), a read-only memory (ROM), an erasable programmable read-only memory (EPROM) or a flash memory, an optical fiber, a portable compact disk read-only memory (CD-ROM), an optical storage device, a magnetic storage device, or any suitable combination thereof. In the embodiments of the present application, the computer-readable storage medium may be any tangible medium including or storing a program, which may be used by an instruction execution system, apparatus or device or used in combination therewith. In the embodiments of the present application, the computer-readable signal medium may include a data signal included in a baseband or propagated as part of a carrier which carries computer-readable program codes. This propagated data signal may take many forms, including but not limited to, an electromagnetic signal, an optical signal, or any suitable combination of the above. The computer-readable signal medium may also be any computer-readable medium other than the computer-readable storage medium. The computer-readable signal medium may send, propagate, or transmit programs used by or used in combination with the instruction execution system, apparatus or device. The program codes contained in the computer-readable medium may be transmitted using any appropriate medium, including but not limited to: a wire, an optical cable, an radio frequency (RF), etc., or any suitable combination thereof.

The computer-readable medium may be contained in the server, also may also exist alone while not be assembled into the server. The computer-readable medium carries one or more programs, which, when executed by the server, cause the server to: acquire a frame rate of an application on a terminal in response to detecting that a peripheral mode of the terminal is not activated; determine whether a user is acquiring screen information of the terminal in response to the frame rate satisfying a screen-off condition; and control the screen to enter an immediate dimming mode in response to a determination result indicating that the user does not acquire the screen information of the terminal.

One or more programming languages or a combination thereof may be used to compile computer program codes for performing the operations in the embodiments of the present application, wherein the programming languages include object-oriented programming languages, such as Java, Smalltalk and C++, as well as conventional procedural programming languages, such as the “C” language or similar programming languages. The program codes may be executed entirely on a user computer, partly on a user computer, as a stand-alone software package, partly on the user computer and partly on a remote computer, or entirely on a remote computer or a server. In a case of the remote computer, the remote computer may be connected to the user computer through any type of network (including a local area network (LAN) or wide area network (WAN)), or may be connected to an external computer (e.g., using an Internet service provider via the Internet).

Each embodiment in the present specification is described in a progressive manner, the same and similar parts between the embodiments may refer to each other, and each embodiment focuses on the differences from other embodiments. For the system and the system embodiments, since they are basically similar to the method embodiments, the description is relatively simple. For related parts, please refer to the part of the description of the method embodiments. The system and the system embodiments described above are merely illustrative, wherein the units described as separate components may or may not be physically separated. The components displayed as units may or may not be physical units, i.e., may be located in one place, or may also be distributed on a plurality of network units. Part or all of the modules might be selected according to actual needs to achieve the object of the solution of this embodiment. Those of ordinary skill in the art might understand and implement the present application, without paying any creative work.

The technical solutions provided by the present application are detailed as above. Specific examples are used herein to illustrate the principles and embodiments of the present application. The description of the above embodiments is only used to help the understanding of the methods and core ideas of the present application. At the same time, for those skilled in the art, according to the ideas of the present application, there will be changes in the specific embodiments and the scope of application. In summary, the content of the present description should not be construed as a limitation of the present application.

The foregoing descriptions are merely some embodiments of the present application, and are not intended to limit the present application. Within the spirit and principles of the present application, any modifications, equivalent substitutions, improvements, etc., are within the protection scope of the present application.

1. A differential signal transmission circuit, wherein the differential signal transmission circuit is formed on a surface layer of a circuit board and comprises a peripherally closed pattern, a first pattern, a second pattern, and a third pattern, wherein the first pattern, the second pattern, and the third pattern are formed by drilling truncation holes at preset positions of a surface metal pattern, wherein the peripherally closed pattern, the first pattern, the second pattern, and the third pattern are all made of metal material, and wherein
the first pattern, the second pattern, and the third pattern are all surrounded by the peripherally closed pattern;
the first pattern, the second pattern, and the third pattern are isolated by a dielectric;
the first pattern and the second pattern are axisymmetric;
the first pattern and the second pattern are respectively connected to an inner signal layer by means of an inner wall plating layer of the circuit board; and
the third pattern is used to form a return current path.

2. (canceled)

3. The differential signal transmission circuit according to claim 1, wherein the third pattern is connected to the peripherally closed pattern through a preset pattern arranged on the surface layer of the circuit board.

4. The differential signal transmission circuit according to claim 3, wherein the preset pattern is arranged on an axis of symmetry of the first pattern and the second pattern.

5. The differential signal transmission circuit according to claim 3, wherein the preset pattern is made of the metal material.

6. The differential signal transmission circuit according to claim 1, wherein a differential impedance of the first pattern and the second pattern is within a preset impedance range.

7. The differential signal transmission circuit according to claim 6, wherein the preset impedance range is 85-100Ω.

8. A circuit board, comprising a differential signal transmission circuit, wherein the differential signal transmission circuit is formed on a surface layer of the circuit board and comprises a peripherally closed pattern, a first pattern, a second pattern, and a third pattern, wherein the first pattern, the second pattern, and the third pattern are formed by drilling truncation holes at preset positions of a surface metal pattern, wherein the peripherally closed pattern, the first pattern, the second pattern, and the third pattern are all made of metal material, and wherein
the first pattern, the second pattern, and the third pattern are all surrounded by the peripherally closed pattern;
the first pattern, the second pattern, and the third pattern are isolated by a dielectric;
the first pattern and the second pattern are axisymmetric;
the first pattern and the second pattern are respectively connected to an inner signal layer by means of an inner wall plating layer of the circuit board; and
the third pattern is used to form a return current path.

9. The circuit board according to claim 8, wherein
the surface layer comprises the surface metal pattern, the surface metal pattern comprises from outside to inside: the peripherally closed pattern, an anti-pad, a pad, and a center hole, truncation holes are drilled at preset positions on the surface metal pattern to form the first pattern and the second pattern on the pad, which are asymmetrically distributed and not connected to each other; and the third pattern is disposed on a symmetry axis of the first pattern and the second pattern and is connected to the peripherally closed pattern via a preset pattern to form a return current path.

10. The circuit board according to claim 8, wherein the circuit board is a printed circuit board.

11. An electronic device, comprising a circuit board, the circuit board comprising a differential signal transmission circuit, wherein the differential signal transmission circuit is formed on a surface layer of the circuit board and comprises a peripherally closed pattern, a first pattern, a second pattern, and a third pattern, wherein the first pattern, the second pattern, and the third pattern are formed by drilling truncation holes at preset positions of a surface metal pattern, wherein the peripherally closed pattern, the first pattern, the second pattern, and the third pattern are all made of metal material, and wherein
the first pattern, the second pattern, and the third pattern are all surrounded by the peripherally closed pattern;
the first pattern, the second pattern, and the third pattern are isolated by a dielectric;
the first pattern and the second pattern are axisymmetric;
the first pattern and the second pattern are respectively connected to an inner signal layer by means of an inner wall plating layer of the circuit board; and
the third pattern is used to form a return current path.

12. A method for manufacturing the differential signal transmission circuit according to claim 1, the method comprising:
drilling the truncation holes at the preset positions on the surface metal pattern to form the first pattern, the second pattern, and the third pattern, wherein the surface metal pattern comprises from outside to inside: the peripherally closed pattern, an anti-pad, a pad, and a center hole; the pad is annular or in a shape of a rectangular frame; the preset positions are located on a pattern of the pad; the truncation holes have a preset radius; the first pattern and the second pattern are axisymmetric; and the first pattern, the second pattern, and the third pattern are separated from each other;
simulating the first pattern and the second pattern to generate an impedance simulation result of the first pattern and the second pattern; and
adjusting an impedance of the first pattern and an impedance of the second pattern according to the impedance simulation result.

13. The method for manufacturing the differential signal transmission circuit according to claim 12, wherein acquiring the preset positions comprises:
invoking a simulation tool to perform simulated biasing on a center position of each of the truncation holes; and
in response to the impedance simulation result of the first pattern and the second pattern being within a preset impedance range, drilling the truncation holes using the center position of the truncation holes as the preset positions and a radius of the truncation holes as the preset radius.

14. The method for manufacturing the differential signal transmission circuit according to claim 12, wherein the adjusting the impedance of the first pattern and the impedance of the second pattern according to the impedance simulation result comprises:
adjusting a center position and the preset radius of one or more of the truncation holes.

15. The method for manufacturing the differential signal transmission circuit according to claim 13, wherein the adjusting the impedance of the first pattern and the impedance of the second pattern according to the impedance simulation result further comprises:
in response to the impedance of the first pattern and the impedance of the second pattern being greater than a maximum value of the preset impedance range, filling the truncation holes and the center hole with a dielectric material so that the impedance of the first pattern and the impedance of the second pattern are reduced; and
in response to the impedance of the first pattern and the impedance of the second pattern being less than a minimum value of the preset impedance range, adjusting the preset positions, and drilling truncation holes at the preset positions on the surface metal pattern again to form the first pattern, the second pattern and the third pattern.

16. The method for manufacturing the differential signal transmission circuit according to claim 15, wherein the dielectric material is resin.

17. The method for manufacturing the differential signal transmission circuit according to claim 16, wherein the resin has a relative dielectric constant of 3.5.

18. The method for manufacturing the differential signal transmission circuit according to claim 12, further comprising, prior to drilling the truncation holes at the preset positions on the surface metal pattern, identifying the surface metal pattern.

19. The method for manufacturing the differential signal transmission circuit according to claim 18, wherein, in response to an identification result indicating that the peripherally closed pattern is annular, the method further comprises:
backfilling a dielectric material between the first pattern and the second pattern;
drilling a central ground hole in a center of the peripherally closed pattern, wherein a radius of the central ground hole is a first preset radius;
plating a metal layer on an inner wall of the central ground hole; and
manufacturing a metal wire along an axis of symmetry of the first pattern and the second pattern, so that the central ground hole is electrically connected to the peripherally closed pattern.

20. The method for manufacturing the differential signal transmission circuit according to claim 19, wherein the first preset radius is less than a shortest distance from the center to the first pattern.

21. The method for manufacturing the differential signal transmission circuit according to claim 18, in response to an identification result indicating that the peripherally closed pattern is in a shape of a rectangular frame, prior to drilling the truncation holes at the preset positions of the surface metal pattern, further comprising:
manufacturing a metal connection pattern between a long side of the pad and the peripherally closed pattern, so that the pad is electrically connected to the peripherally closed pattern.

22. (canceled)
